(19) United States
(12) Patent Application Publication
(10) Pub. No.: US 2019/0235588 A1
(43) Pub. Date: Aug. 1, 2019

(54) ELECTRICAL DEVICE, CIRCUIT BOARD, AND METHOD OF IDENTIFYING A TYPE OF A HOUSING OF AN ELECTRICAL DEVICE

(71) Applicant: Fujitsu Technology Solutions Intellectual Property GmbH, Munchen (DE)

(72) Inventors: Diana Langner, München (DE); Bernhard Kannler, München (DE); Martin Schmutzer, München (DE); Andreas Maier, München (DE); Georg Ahn, München (DE)

(21) Appl. No.: 16/260,729

(22) Filed: Jan. 29, 2019

(30) Foreign Application Priority Data
Jan. 29, 2018 (DE) 10 2018 101 903.3

(51) Int. Cl. G06F 1/18; H05K 1/18; H05K 5/00; H05K 1/02

(52) U.S. Cl. CPC G06F 1/184; H05K 1/181; H05K 2201/2072; H05K 1/0203; H05K 2201/10409; H05K 5/0026

(57) ABSTRACT

An electrical device includes a housing, a circuit board including at least one fastening means, at least one fastening element configured to fix the circuit board on the housing by the at least one fastening means, and a microcontroller arranged on the circuit board, wherein an electrical contact electrically connected to the microcontroller is arranged on the circuit board to be spaced apart from the fastening means by a specified spacing, the fastening element has a housing-specific diameter at an end facing the circuit board, and the microcontroller is configured to determine a type of the housing on the basis of whether the fastening element contacts the at least one electrical contact.

### TECHNICAL FIELD

This disclosure relates to an electrical device, in particular a computer, comprising a housing, a circuit board that comprises at least one fastening means, and at least one fastening element configured to fix the circuit board on the housing by the at least one fastening means, as well as a circuit board and a method of identifying a type of a housing of an electrical device, in particular a computer.

### BACKGROUND

Nowadays, various electrical devices often use structurally identical circuit boards. For this purpose, the structurally identical circuit boards are installed in different housings, for example. Housing-specific information is sometimes required to operate the electrical device. Information of this kind comprises, for example, fan characteristics for it to be possible to control fans, installed in the electrical device, in accordance with the fan characteristics that are characteristic of the housing.

DE 10 2013 111 975 B3 describes a circuit board comprising a plurality of fastening means, of which two are each connected to a microcontroller on the circuit board. Depending on a housing type in which the circuit board is installed, the circuit board is fixed on a housing of a computer using the first or the second fastening means connected to the microcontroller. The microcontroller identifies whether the first or second fastening means is used for fixing on the housing, and thus determines a type of the housing.

A disadvantage is that a relatively large amount of space is required on the circuit board for two fastening means, only one of which is ever actually used. The second fastening device each connected to the microcontroller is redundant. Furthermore, a relatively complex board layout of the circuit board is required to connect two fastening means to the microcontroller.

It could therefore be helpful to provide an alternative device and an improved method making it possible to determine a type of a housing of an electrical device in which a circuit board is installed.

### SUMMARY

We provide an electrical device including a housing, a circuit board including at least one fastening means, at least one fastening element configured to fix the circuit board on the housing by the at least one fastening means, and a microcontroller arranged on the circuit board, wherein an electrical contact electrically connected to the microcontroller is arranged on the circuit board to be spaced apart from the fastening means by a specified spacing, the fastening element has a housing-specific diameter at an end facing the circuit board, and the microcontroller is configured to determine a type of the housing on the basis of whether the fastening element contacts the at least one electrical contact.

We also provide a circuit board including at least one fastening means that fastens the circuit board to a housing by at least one fastening element, a microcontroller arranged on the circuit board, and at least one electrical contact electrically connected to the microcontroller and arranged on the circuit board to be spaced apart from the fastening means by a specified spacing, wherein the microcontroller is configured to determine a type of the housing on the basis of whether an end of the fastening element facing the circuit board contacts the at least one electrical contact.

We further provide a method of identifying a type of a housing of an electrical device, the electrical device including a circuit board fastened to the housing by at least one fastening element, the method including assessing, by a microcontroller, whether an end of the fastening element facing the circuit board contacts an electrical contact attached to the circuit board to be spaced apart from the fastening means by a specified spacing.

### BRIEF DESCRIPTION OF THE DRAWINGS

FIG. 1 is a perspective view of a computer according to an example.

FIG. 2 shows a detail of a circuit board according to an example.

FIG. 3 is a schematic view of a circuit that identifies a type of a housing of a computer according to an example.

### LIST OF REFERENCE CHARACTERS

1 computer
2 housing
3 wall of the housing
4 circuit board
5, 5′, 5″ spacer
6, 6′ opening
7 screw
8 electrical contact
9 electrical connection
10 microcontroller
11 GPIO pin
12 non-volatile memory module
13 fan
14 ground contact
15 pull-up resistor
16 processor
X specified spacing
D, D′ diameter
VCC supply voltage
GND ground potential

### DETAILED DESCRIPTION

We provide an electrical device, in particular a computer. A microcontroller is furthermore arranged on the circuit board. An electrical contact electrically connected to the microcontroller is arranged on the circuit board to be spaced apart from the fastening means by a specified spacing. The fastening element has a housing-specific diameter at an end facing the circuit board. The microcontroller is configured to determine a type of the housing on the basis of whether the fastening element contacts the at least one electrical contact.

In this manner, an assessment of whether or not the at least one electrical contact is contacted by the fastening element makes it possible to install structurally identical circuit boards in different housing types and, by using fastening elements having a housing-specific diameter, reliably identify each housing type on the basis of the size of the diameter. Different housing types are, for example, a desktop housing, server housing, all-in-one PC housing and the like.

Precisely one electrical contact may be arranged on the circuit board to be at a specified spacing from the at least one fastening means, or a plurality of electrical contacts may be arranged on the circuit board to be at the same specified spacing from the at least one fastening means. For example, two housing types can be distinguished by exactly one or multiple electrical contacts equally remote from the fastening means. A first housing type corresponds to a housing in which fastening elements having a small diameter are used, i.e. fastening elements are used having a diameter at which the fastening element does not contact the electrical contact. A second housing type corresponds to a housing in which fastening elements having a larger diameter are used, at which the electrical contact is contacted by the fastening element.

A plurality of electrical contacts (8) may be arranged on the circuit board to be at different specified spacings from the at least one fastening means. If a plurality of electrical contacts is used on the circuit board, which contacts are at different specified spacings from the fastening means, it is possible to distinguish among more than two housing types, according to how many, if any, of the electrical contacts are contacted by fastening elements having housing-specific diameters.

The microcontroller may furthermore be configured to load housing-specific settings from a non-volatile memory module on the basis of the identified housing type. This makes it possible to adapt operation of the electrical device to the identified housing type. It is expedient in particular to load housing-specific fan characteristics from the non-volatile memory module.

The at least one fastening element may be configured to electrically connect the circuit board to the housing. Furthermore, at least one ground contact may be attached to the circuit board in a region of the at least one fastening means, which ground contact reaches closer to the at least one fastening means than the at least one electrical contact does, at least in some examples. This ensures grounding of the circuit board, in particular also irrespective of which fastening elements are used.

The at least one fastening element consists, for example, of an electrically conductive material or is at least coated therewith. The fact that the at least one ground contact reaches at least in part closer to the fastening means than the at least one electrical contact does, ensures that even the fastening elements having the smallest diameter ensure reliable grounding of the circuit board. The microcontroller is furthermore designed, for example, to ascertain whether the at least one electrical contact connects, by the contacting via the fastening element, to a specified electrical potential, in particular a ground potential.

The at least one ground contact may be semi-circular and extends in a region electrically isolated from the at least one electrical contact. This ensures electrical isolation between the at least one ground contact and the at least one electrical contact if no fastening element is inserted or if a fastening element is inserted that does not reach as far as to the at least one electrical contact. As a result, reliable grounding of the circuit board is ensured and at the same time incorrect detection of the housing type owing to unintended contacting of the ground contact by the at least one electrical contact is prevented.

The at least one electrical contact may connect to a GPIO pin of the microcontroller. This allows for simple assessment of the state of the contacting of the at least one electrical contact, i.e. whether or not the electrical contact is contacted.

A pull-up resistor may furthermore connect to the at least one electrical contact. In this example, the microcontroller ascertains whether or not the at least one electrical contact is grounded by a high signal level or a low signal level being detected at the microcontroller. In a lack of contacting by the fastening element, there is a high signal level at the microcontroller which is drawn to a low signal level when the fastening element contacts the at least one electrical contact.

We also provide a circuit board comprising at least one fastening means that fastens the circuit board to a housing by at least one fastening element. The circuit board furthermore comprises at least one microcontroller arranged on the circuit board, and at least one electrical contact electrically connected to the microcontroller and arranged on the circuit board to be spaced apart from the fastening means by a specified spacing. The microcontroller identifies a type of the housing on the basis of whether an end of the fastening element that faces the circuit board contacts the at least one electrical contact.

A circuit board of this kind is a cost-effective means of identifying a housing type. The circuit board described herein requires only a small amount of space on the circuit board for the means of identifying the housing type. Advantages and examples of the circuit board substantially correspond to the advantages and the examples of the circuit board.

We also provide a method of identifying a type of a housing of an electrical device, in particular a computer. The electrical device comprises a circuit board fastened to the housing by at least one fastening element. The method comprises the following step: assessing, by a microcontroller, whether an end of the fastening element facing the circuit board contacts an electrical contact attached to the circuit board to be spaced apart from the fastening means by a specified spacing.

The method may further comprise the step of: loading at least one housing-specific setting on the basis of the assessment by the microcontroller. Loading the at least one housing-specific setting comprises loading housing-specific fan characteristics, for example. Furthermore, the at least one housing-specific setting is loaded from a BIOS of a computer, for example. The step of identifying the type of the housing may be carried out each time a computer is booted. For example, the step of identifying the type of the housing is carried out during a power-on self-test (POST) of a computer.

Further advantages are disclosed in the following description of examples. The examples are described with reference to the accompanying drawings. In the drawings, the same reference characters are used for elements having substantially the same function, but the elements do not need to be identical in all details. Elements having the same reference character may be described in more detail only when they first appear.

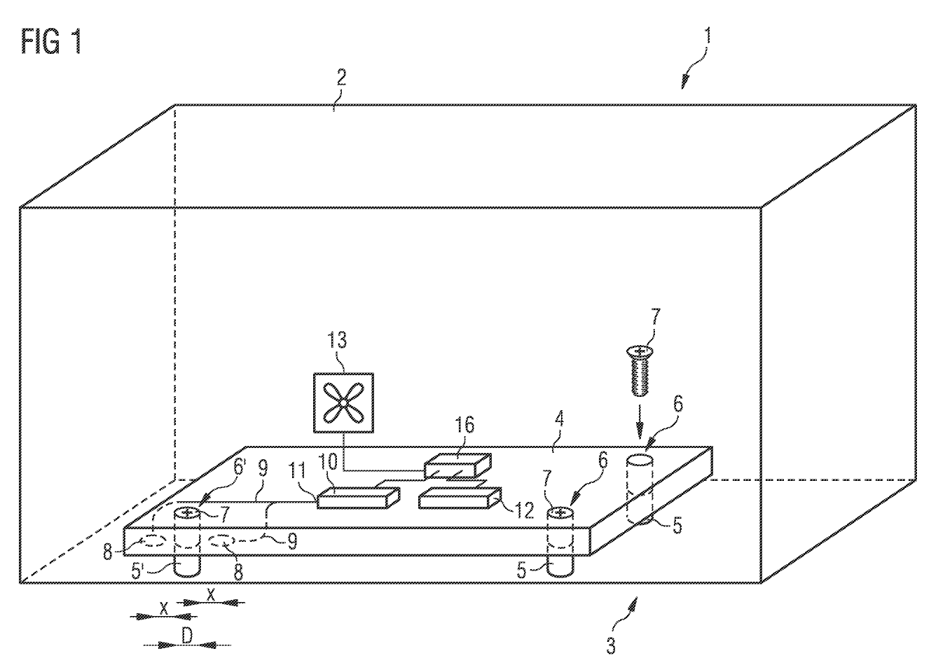

FIG. 1 is a perspective view of a computer 1 having a housing 2. A circuit board 4, in this example a motherboard of the computer 1, is fastened to a wall 3 of the housing 2. Electrically conductive spacers 5, 5′ are used to fasten the circuit board 4 to the wall 3 of the housing 2, which spacers are arranged between the wall 3 and the circuit board 4.

At an end thereof facing the wall 3 of the housing 2 the spacers 5, 5′ comprise a flange-mounted pin (not visible) having an external thread by which the spacers 5, 5′ are screwed to the wall 3. Alternatively, the spacers 5, 5′ may be riveted, welded or connected to the wall 3 in another manner. At an end of the spacers 5, 5′ facing the circuit board 4, the spacers 5, 5′ each comprise an internal thread. The spacers 5, 5′ are arranged in the housing 2 such that an upper side of the spacers 5, 5′ adjoins openings 6, 6′ in the circuit board 3, through which openings 6, 6′ screws 7 are guided. The screws 7 are screwed to the internal threads of the spacers 5, 5′. The circuit board 4 is fixed on the housing 2 in this manner. Alternative means of fastening the circuit board 4 to the housing 2 are of course possible.

Two electrical contacts 8 are attached to a side of the circuit board 4 facing the spacer 5′, in the region of one of the openings 6′. The contacts 8 are wires of the circuit board 4 comprising open solder resist on a surface of the circuit board 4. The electrical contacts 8 are arranged on opposite sides of the opening 6′ to be at a specified spacing X from the opening 6′. The specified spacing X is a few millimeters. The electrical contacts 8 are arranged spaced apart from the opening 6′, i.e. the electrical contacts 8 do not touch the opening 6′.

The electrical contacts 8 connect, by electrical connections 9, to a microcontroller 10 arranged on the circuit board 4. In this example, the microcontroller 10 is part of a chipset, for example, what is known as a platform controller hub (PCH), comprising at least one GPIO pin 11. The electrical connections 9 are attached to the GPIO pin 11. Alternatively, the microcontroller 10 may be an independent component.

The spacers 5, 5′ have a diameter D in parallel with a main plane of extension of the circuit board 4. In the system construction shown in FIG. 1, the diameter D is sufficiently small that the spacer 5′ does not contact the electrical contacts 8 at the opening 6′. The diameter D of the spacers 5, 5′ is specific for a type of the housing 2. If a structurally identical circuit board 4 of this kind is installed in a housing of a different type, spacers are used that have a larger diameter D′. The larger diameter D′ is selected such that at least one of the electrical contacts 8 is then contacted by a spacer of this kind having diameter D′.

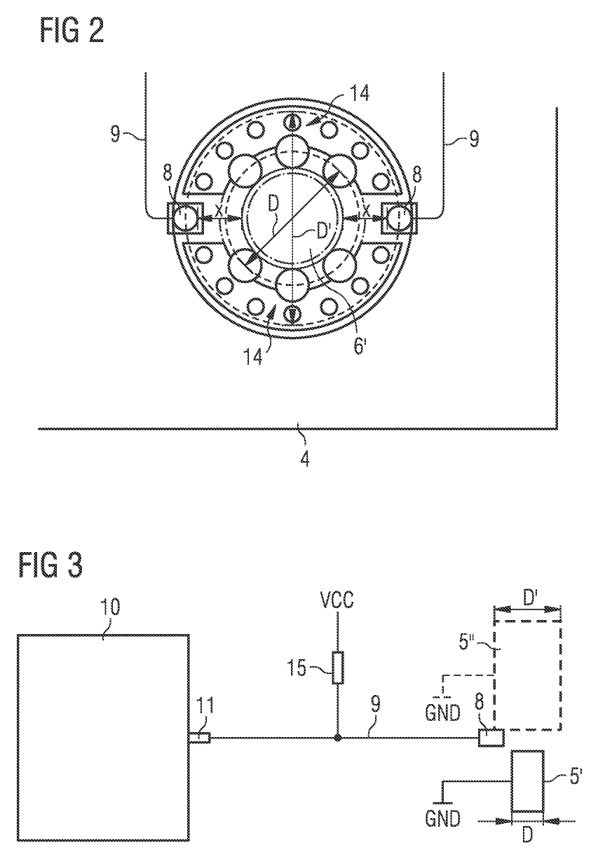

Each time the computer is booted, the microcontroller 10 assesses whether or not the spacer 5′ contacts at least one of the electrical contacts 8. In the example according to FIG. 1, this assessment always shows that the electrical contacts 8 are not contacted by the spacer 5′. In the housing of the other type comprising spacers having a larger diameter D′, the microcontroller 10 will ascertain that the electrical contacts 8 are contacted by the larger spacer. The assessment of the housing type is described in more detail with reference to FIGS. 2 and 3.

A non-volatile memory module 12 and a processor 16 are furthermore arranged on the circuit board 4. The processor 16 connects to the microcontroller 10 and the non-volatile memory module 12.

Each time the computer 1 is booted, a BIOS, stored in the non-volatile memory module 12, is loaded by the processor 16. The BIOS checks the housing type determined by the microcontroller 10 and loads housing-specific settings from the non-volatile memory module 12 according to the housing type determined. The housing-specific settings comprise, for example, fan characteristics in accordance with which a fan 13 of the computer 1 can be controlled in a housing-specific manner. Alternatively, it is possible for the microcontroller 10 to load the housing-specific settings itself and accordingly undertake housing-specific control operations.

FIG. 2 shows a detail of the circuit board 4 of the computer 1 according to FIG. 1. FIG. 2 shows a lower side, i.e. the side of the circuit board 4 facing the wall 3 of the housing 2 in FIG. 1 in a region of the opening 6′. The electrical contacts 8 are located on opposing sides of the opening 6′ to each be at a specified spacing X from the opening 6′. The electrical connections 9 leading to the microcontroller 10 (not shown in FIG. 2) lead away from the electrical contacts 8.

Two ground contacts 14 arranged in two semicircles around the opening 6′ are furthermore located on the circuit board 4. The ground contacts 14 are interrupted in regions of the electrical contacts 8. The ground contacts 14 reach at least partly closer to the opening 6′ than the electrical contacts do. The ground contacts 14 ground the circuit board 4 for safety purposes. The fact that the ground contacts 14 reach at least partly closer to the opening 6′ ensures that even spacers that do not contact the electrical contacts 8, as shown in the example according to FIG. 1, for example, ensure grounding of the circuit board 4.

FIG. 2 furthermore schematically shows the different diameters D, D′ of the different housing-specific spacers. It can thus clearly be seen that spacers having the diameter D do not contact the electrical contacts 8, but spacers having the larger diameter D′ do contact the electrical contacts 8. Both the spacers having the diameter D and the spacers having the diameter D′ contact the ground contacts 14.

FIG. 3 is a schematic view of a circuit that identifies a type of a housing 2 of a computer 1, as used in the computer 1 according to FIG. 1, for example. FIG. 3 shows the microcontroller 10 comprising the GPIO pin 11. FIG. 3 furthermore shows one of the electrical contacts 8 connected to the GPIO pin 11 of the microcontroller 10 by the electrical connection 9. For the purpose of comparison, FIG. 3 furthermore shows two different spacers 5′, 5″, one of which has the diameter D and the other of which has the larger diameter D′. In a first housing type spacers such as the spacer 5′ shown here are used, and in a second housing type spacers such as the spacer 5″ shown here are used. The diameter D of the spacer 5′ is, for example, 5.7 millimeters, and the diameter D′ of the spacer 5″ is, for example, 10 to 12 millimeters.

The spacers 5′, 5″ are produced from an electrically conductive material and are in electrical contact with the housing 2 (not shown in FIG. 3) such that the spacers 5′, 5″ are grounded by the housing 2. A pull-up resistor 15 furthermore connects to the electrical connection 9. The pull-up resistor 15 connects the GPIO pin 11 to a supply voltage VCC.

If, as shown in the example according to FIG. 1, a spacer 5′ having the diameter D is used to fasten the circuit board 4 in the housing 2, the spacer 5′ does not contact the electrical contact 8. The electrical contact 8 is therefore not connected to a ground potential GND of the housing. In this example, a high signal level is present at the GPIO pin 11 of the microcontroller 10 on account of the supply voltage VCC and the pull-up resistor 15. The high signal level at the GPIO pin 11 thus indicates the first housing type to the microcontroller 10.

If the spacer 5″ having the diameter D′ is used instead of the spacer 5′ having the diameter D, the spacer 5″ contacts the electrical contact 8 and draws the contact electrically to the ground potential GND. The signal present at the GPIO pin 11 is drawn to a low signal level in this manner. The low signal level thus indicates to the microcontroller 10 that the spacer 5″ is used instead of the spacer 5′, which indicates the second housing type to the microcontroller 10. In this manner, the microcontroller can ascertain, on the basis of the signal present at the GPIO pin 11 (high or low signal level), whether the spacer 5′ or the spacer 5″ is used in the housing in which the circuit board 4 is installed. If, as described above, the spacers 5′ are installed exclusively in a first housing type and the spacers 5″ are installed exclusively in a second housing type, the microcontroller 10 can thus clearly ascertain the housing type in which the circuit board 4, comprising the circuit shown, is installed.

What is claimed is:

1. An electrical device comprising:
a housing,
a circuit board comprising at least one fastening means,
at least one fastening element configured to fix the circuit board on the housing by the at least one fastening means, and
a microcontroller arranged on the circuit board,
wherein
an electrical contact electrically connected to the microcontroller is arranged on the circuit board to be spaced apart from the fastening means by a specified spacing,
the fastening element has a housing-specific diameter at an end facing the circuit board, and
the microcontroller is configured to determine a type of the housing on the basis of whether the fastening element contacts the at least one electrical contact.

2. The electrical device according to claim 1, wherein precisely one electrical contact is arranged on the circuit board to be at a specified spacing from the at least one fastening means, or a plurality of electrical contacts is arranged on the circuit board to be at the same specified spacing from the at least one fastening means.

3. The electrical device according to claim 1, wherein a plurality of electrical contacts is arranged on the circuit board to be at different specified spacings from the at least one fastening means.

4. The electrical device according to claim 1, wherein the microcontroller is furthermore configured to load housing-specific settings from a non-volatile memory module, on the basis of the identified housing type.

5. The electrical device according to claim 1, wherein the at least one fastening element is configured to electrically connect the circuit board to the housing, and at least one ground contact is attached to the circuit board in a region of the at least one fastening means, which ground contact at least partially reaches closer to the at least one fastening means than the at least one electrical contact.

6. The electrical device according to claim 5, wherein the at least one ground contact is semi-circular and extends in a region electrically isolated from the at least one electrical contact.

7. The electrical device according to claim 1, wherein the at least one electrical contact electrically connects to a GPIO pin of the microcontroller.

8. The electrical device according to claim 1, wherein a pull-up resistor furthermore connects to the at least one electrical contact.

9. The electrical device according to claim 1, wherein the electrical device is a computer.

10. A circuit board comprising:
at least one fastening means that fastens the circuit board to a housing by at least one fastening element,
a microcontroller arranged on the circuit board, and
at least one electrical contact electrically connected to the microcontroller and arranged on the circuit board to be spaced apart from the fastening means by a specified spacing,
wherein the microcontroller is configured to determine a type of the housing on the basis of whether an end of the fastening element facing the circuit board contacts the at least one electrical contact.

11. A method of identifying a type of a housing of an electrical device, the electrical device comprising a circuit board fastened to the housing by at least one fastening element, the method comprising:
assessing, by a microcontroller, whether an end of the fastening element facing the circuit board contacts an electrical contact attached to the circuit board to be spaced apart from the fastening means by a specified spacing.

12. The method according to claim 11, further comprising loading at least one housing-specific setting on the basis of the assessment by the microcontroller.

13. The method according to claim 12, wherein loading the at least one housing-specific setting at least comprises loading housing-specific fan characteristics.

14. The method according to claim 12, wherein the at least one housing-specific setting is loaded from a BIOS of a computer.

15. The method according to claim 11, wherein identifying the type of the housing is carried out each time a computer is booted.

16. The method according to claim 11, wherein the electrical device is a computer.
